(19) United States
(12) Patent Application Publication
(10) Pub. No.: US 2020/0007100 A1
(43) Pub. Date: Jan. 2, 2020

(54) DISTRIBUTED DARLINGTON PAIR AMPLIFIER

(71) Applicant: MACOM Technology Solutions Holdings, Inc., Lowell, MA (US)

(72) Inventor: Keigo Kamozaki, San Jose, CA (US)

(21) Appl. No.: 16/023,797

(22) Filed: Jun. 29, 2018

(51) Int. Cl. H03F 3/60; H03F 3/19; H03F 3/00

(52) U.S. Cl. CPC H03F 3/605; H03F 2200/93; H03F 3/005; H03F 3/19

(57) ABSTRACT

Aspects of a distributed Darlington pair amplifier are described. In one example, a distributed amplifier device includes a number of distributed amplifier cells. The distributed amplifier cells can each include an input coupled to an input line and an output coupled to an output line. The amplifier device also includes a radio frequency input coupled to the input line and a radio frequency output coupled to the output line. One or more of the distributed amplifier cells can include a Darlington transistor pair rather than a common source transistor. The Darlington transistor pair can have a smaller gate-source capacitance than the common source transistor. This results in the ability to omit a series capacitor used with the common source transistor, improving the noise figure and gain over a range of operating frequencies for the distributed Darlington pair amplifier.

### BACKGROUND

The semiconductor industry continues to see demands for devices having lower cost, size, and power consumption, particularly for monolithic microwave integrated circuit (MMIC) devices. MIMIC devices encompass integrated circuits (IC) designed for operation over microwave frequencies. MMIC devices can be relied upon for mixing, power amplification, low-noise amplification, and high-frequency switching, among other operations.

Distributed amplifiers are amplifiers that rely, in part, on transmission line theory to achieve a relatively larger gain-bandwidth product than could be achieved by conventional circuits. Distributed amplifiers can also be constructed from group III-V direct bandgap semiconductor technologies. The higher bandgaps and electron mobility provided by those devices can lead to higher electron velocity and breakdown voltages, among other benefits.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments. In the drawings, like reference numerals designate like or corresponding, but not necessarily the same, elements throughout the several views.

FIG. 1 illustrates an example distributed amplifier according various embodiments described herein.

FIG. 2 illustrates an example distributed amplifier including Darlington transistor pairs in amplifier cells according various embodiments described herein.

FIG. 3 illustrates the noise figure of the distributed amplifier shown in FIG. 1 according various embodiments described herein.

FIG. 4 illustrates the noise figure of the distributed amplifier shown in FIG. 2 according various embodiments described herein.

FIG. 5 illustrates the gain of the distributed amplifier shown in FIG. 1 according various embodiments described herein.

FIG. 6 illustrates the gain of the distributed amplifier shown in FIG. 2 according various embodiments described herein.

### DETAILED DESCRIPTION

As described above, distributed amplifiers are amplifiers that rely, in part, on transmission line theory to achieve a relatively larger gain-bandwidth product than could be achieved by conventional circuits. Distributed amplifiers can also be constructed from group III-V direct bandgap semiconductor technologies. The higher bandgaps and electron mobility provided by those devices can lead to higher electron velocity and breakdown voltages, among other benefits.

Aspects of a distributed Darlington pair amplifier are described. In one example, a distributed amplifier device includes a number of distributed amplifier cells. The distributed amplifier cells can each include an input coupled to an input line and an output coupled to an output line. The amplifier device also includes a radio frequency input coupled to the input line and a radio frequency output coupled to the output line. One or more of the distributed amplifier cells can include a Darlington transistor pair rather than a common source transistor. The Darlington transistor pair can have a smaller gate-source capacitance than the common source transistor. This results in the ability to omit a series capacitor used with the common source transistor, improving the noise figure (NF) and gain over a range of operating frequencies for the distributed Darlington pair amplifier. The NF is a measure of degradation of the signal-to-noise ratio (SNR) caused by components in a signal chain. Lower values of NF indicate higher performance.

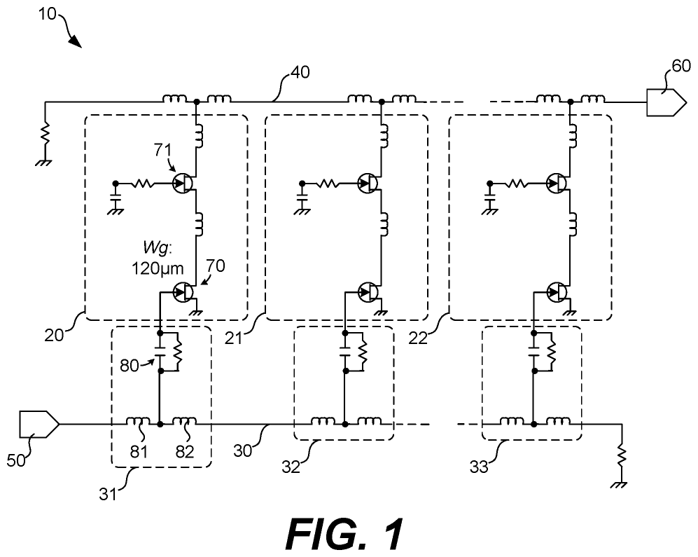

FIG. 1 illustrates a distributed amplifier 10 according various embodiments described herein. The distributed amplifier 10 is provided as an example of an amplifier designed to provide a relatively large gain-bandwidth product as compared to other types or topologies of amplifiers. For example, the distributed amplifier 10 may be designed to provide a relatively constant gain of 10 dB or more over a frequency range from nearly zero to over 30 GHz, although the concepts described herein are not limited to distributed amplifiers operating at any particular level of gain or within any particular range of frequencies. The distributed amplifier 10 can be formed in various ways, such as using discrete components, as an integrated circuit device formed on one or more substrates, or as a combination of discrete components and integrated devices.

The distributed amplifier 10 can be formed using any suitable semiconductor manufacturing process, such as a suitable enhancement mode semiconductor manufacturing process, to form enhancement mode transistor devices. In enhancement mode devices, voltages applied to the gate terminals of the devices increase the conductivity of the devices. In that context, the transistors in the distributed amplifier 10 can be formed as group III-V direct bandgap semiconductor devices (e.g., Gallium Arsenide (GaAs), Indium Phosphide (InP), Indium Gallium Phosphide (InGaP), Aluminum Gallium Arsenide (AlGaAs), etc.). The devices can be formed through an enhancement mode power pseudomorphic high electron mobility transistor (PHEMT) process for use as high efficiency power amplifiers, for example, among other suitable semiconductor manufacturing processes. In other cases, the concepts described herein can be relied upon for use with depletion mode devices with certain design changes.

In other embodiments, the distributed amplifier 10 can be simulated on one or more computing devices. For example, one or more aspects of a semiconductor manufacturing process, such as the dopant distribution, the stress distribution, the device geometry, and other aspects of a manufacturing process to form the distributed amplifier 10 can be simulated. Manufacturing process simulations can be relied upon to model the characteristics of the semiconductor devices (e.g., transistors) and other elements (e.g., resistors, inductors, capacitors, etc.) of the distributed amplifier 10. One or more operational characteristics of the distributed amplifier 10, such as the NF, the gain-bandwidth, and other characteristics can also be simulated. Simulations can be relied upon to model the characteristics of the semiconductor devices (e.g., transistors) and other elements (e.g., resistors, inductors, capacitors, etc.) of the distributed amplifier 10. Thus, the distributed amplifier 10 can be simulated using one or more circuit simulator, semiconductor device modeling, semiconductor process simulation, or related Technology Computer Aided Design (TCAD) software tools.

As shown in FIG. 1, the distributed amplifier 10 includes a number of distributed amplifier cells 20-22, among others. Three amplifier cells 20-22 are illustrated in FIG. 1, but the distributed amplifier 10 can include any suitable number of amplifier cells 20-22. As one example, the distributed amplifier 10 can include eight amplifier cells. The components of the distributed amplifier cells 20-22 are described in further detail below.

The distributed amplifier cells 20-22 are coupled between an input line 30 and an output line 40 in the distributed amplifier 10. The input line 30 can be embodied as a 50Ω transmission line input network to feed the respective inputs of the distributed amplifier cells 20-22. The output line 40 can be embodied as a 50Ω transmission line output network to combine the respective outputs of the distributed amplifier cells 20-22. The input line 30 includes a number of filter units 31-33, among others, and the output line 40 also includes a number of filter units as shown. The input line 30 is electrically coupled at one end to a radio frequency (RF) input 50, and the output line 40 is electrically coupled at one end to an RF output 60.

Among other components, the distributed amplifier cell 20 includes a common source transistor 70 and a common gate transistor 71. The distributed amplifier cells 21 and 22 are similar in form to the distributed amplifier cell 20. To achieve higher output power from the distributed amplifier 10, the width of the gate of the common source transistor 70 of the distributed amplifier cell 20 can be increased in size. For example, the width of the gate of the common source transistor 70 can be formed to be 120 μm, as compared to a smaller width, to increase the output power of the distributed amplifier 10. The widths of the gates of the common source transistors in the distributed amplifier cells 21 and 22 can also be increased to 120 μm, for example, to increase the output power of the distributed amplifier 10. However, the increase of the widths of the gates of the common source transistors in the distributed amplifiers 20-22 leads to an increase in the gate-source capacitance, C_{gs}, of the common source transistors. For a gate width of 120 μm, the C_{gs} of the common source transistor 70 can be 0.38 pF, which is larger than that for gate widths of less than 120 μm.

The filter units 31-33 in the gate line network of the input line 30 form a type of constant-k filter network. The filter units 31-33 are embodied as lumped inductor (L) and capacitor (C) elements. The parasitic inductances and/or capacitances of the transistors in the distributed amplifier cells 20-22 can, in part, form the lumped elements in the filter units 31-33. For example, the C_{gs} capacitance of the common source transistor 70 contributes to the filter unit 31. The C_{gs} of the each of the common source transistors in the distributed amplifier cells 21 and 22 also contribute to the filter units 32 and 33, respectively, in the gate line network of the input line 30.

As noted above, to achieve higher output power from the distributed amplifier 10, the widths of the gates of the common source transistors of the distributed amplifier cells 20-22 can be increased in size. When the gate widths are increased, the relatively larger values of C_{gs} in those transistors are realized in the gate line network and result in a lower cut-off frequency for the distributed amplifier 10. This lower cut-off frequency is undesirable for many applications in which the distributed amplifier 10 is used.

To reduce the equivalent value of C_{gs}, a series capacitor 80 may be included as part of a parallel R-C circuit in the filter unit 31, as shown in FIG. 1. The series capacitor 80 may be embodied as a 0.15 pF capacitance, as one example. Thus, according to the example shown in FIG. 1, the filter unit 31 includes the C_{gs} capacitance of the common source transistor 70, the series capacitor 80 as part of a parallel R-C circuit, and the inductors 81 and 82. The filter units 32 and 33 include capacitors similar to the series capacitor 80 in the filter unit 31 and inductors similar to the inductors 81 and 82 in the filter unit 31. The series capacitor 80 in the filter unit 31 (and the series capacitors in the filter units 32 and 33) can be relied upon to balance out the effect of the increased gate widths of the common source transistors in the distributed amplifier cells 21-23. In that way, the cut-off frequency of the distributed amplifier 10 can be increased.

However, the use of the series capacitors in the filter units 31-33 results in both lower gain and a higher NF, particularly at low frequencies, for the distributed amplifier 10. In direct conversion receivers, a low NF and high linearity are desirable, and there is a high demand for distributed amplifiers having a low NF and high linearity over a wide range of operating frequencies. The series capacitors also require additional space to form in integrated circuit devices, although the trend is to reduce the size of integrated devices.

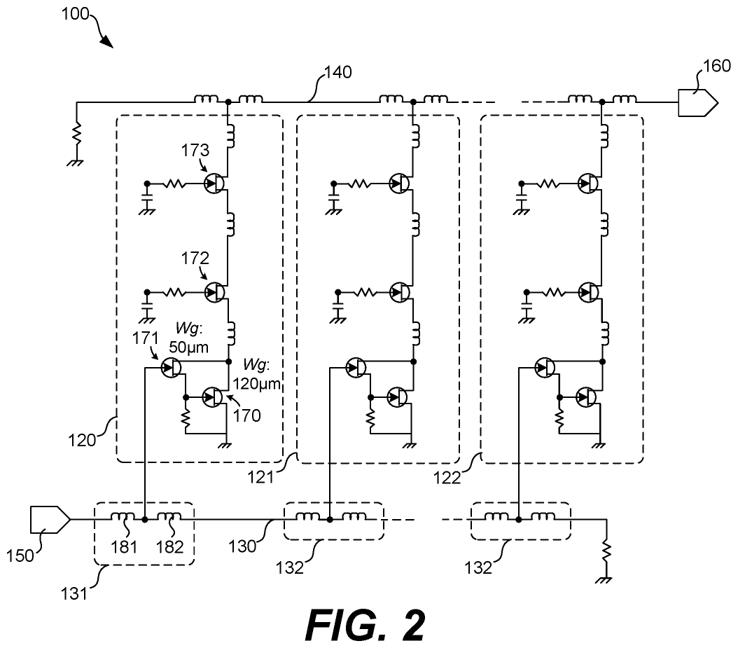

To overcome some of the problems described above, FIG. 2 illustrates an example distributed amplifier 100 including Darlington transistor pairs in amplifier cells according various embodiments described herein. The distributed amplifier 100 can be formed using any suitable semiconductor manufacturing process, such as a suitable enhancement mode semiconductor manufacturing process, to form enhancement mode transistor devices. In enhancement mode devices, voltages applied to the gate terminals of the devices increase the conductivity of the devices. In that context, the transistors in the distributed amplifier 100 can be formed as group III-V direct bandgap semiconductor devices. The devices can be formed through an enhancement mode PHEMT process for use as high efficiency power amplifiers, for example, among other suitable semiconductor manufacturing processes. In other cases, the concepts described herein can be relied upon for use with depletion mode devices with certain design changes.

In other embodiments, the distributed amplifier 100 can be simulated on one or more computing devices. For example, one or more aspects of a semiconductor manufacturing process, such as the dopant distribution, the stress distribution, the device geometry, and other aspects of a manufacturing process to form the distributed amplifier 100 can be simulated. Manufacturing process simulations can be relied upon to model the characteristics of the semiconductor devices (e.g., transistors) and other elements (e.g., resistors, inductors, capacitors, etc.) of the distributed amplifier 100. One or more operational characteristics of the distributed amplifier 100, such as the NF, the gain-bandwidth, and other characteristics can also be simulated. Simulations can be relied upon to model the characteristics of the semiconductor devices (e.g., transistors) and other elements (e.g., resistors, inductors, capacitors, etc.) of the distributed amplifier 100. Thus, the distributed amplifier 100 can be simulated using one or more circuit simulator, semiconductor device modeling, semiconductor process simulation, or related TCAD software tools.

As shown in FIG. 2, the distributed amplifier 100 includes a number of distributed amplifier cells 120-122, among others. Three amplifier cells 120-122 are illustrated in FIG. 2, but the distributed amplifier 100 can include any suitable number of amplifier cells 120-122. As one example, the distributed amplifier 100 includes eight amplifier cells. The distributed amplifier cells 120-122 are coupled between an input line 130 and an output line 140 in the distributed amplifier 100. The input line 130 can be embodied as a 50Ω transmission line input network to feed the respective inputs of the distributed amplifier cells 120-122. The output line 140 can be embodied as a 50Ω transmission line output network to combine the respective outputs of the distributed amplifier cells 120-122. The input line 130 includes a number of filter units 131-133, among others, and the output line 140 also includes a number of filter units as shown. The input line 130 is electrically coupled at one end to an RF input 150, and the output line 140 is electrically coupled at one end to an RF output 160.

Among other components, the distributed amplifier cell 120 includes a Darlington transistor pair of transistors 170 and 171, a first common gate transistor 172, and a second common gate transistor 173. The first common gate transistor 172 and the second common gate transistor 173 are arranged in a stacked cascode configuration of common gate transistors. The distributed amplifier cells 121 and 122 are similar in form to the distributed amplifier cell 120. The Darlington transistor pair in each of the amplifier cells 120-122 is formed as a pair of two transistors connected such that the current amplified by the first, common drain transistor 170 is amplified further by the second, common source transistor 171. The gate of the common source transistor 171 is coupled to a source of the common drain transistor 170. This configuration provides a higher current gain than the transistors 170 and 171 taken separately.

The gate width of the transistor 170 can be different than the gate width of the transistor 171. Particularly, to achieve higher output power from the distributed amplifier 100, the width of the gate of the transistor 170 in the Darlington transistor pair of the amplifier cell 120 can be formed at a relatively large size. For example, the width of the gate of the transistor 170 can be formed to be 120 μm, as compared to a smaller width, to increase the output power of the distributed amplifier 100. The widths of the gates of the common source transistors in the Darlington transistor pairs in the amplifier cells 121 and 122 can also be formed to be 120 μm, for example, to increase the output power of the distributed amplifier 100.

At the same time, the width of the gate of the transistor 171 in the Darlington transistor pair can be formed at a relatively smaller size than the transistor 170. For example, the width of the gate of the transistor 171 can be formed to be 50 μm. Similarly, the width of the gate of the common drain transistors in the Darlington transistor pairs in the amplifier cells 121 and 122 can also be formed to be 50 μm. The C_{gs} capacitance of the transistor 171 can be about 0.16 pF, for example, which is less than the approximate C_{gs} capacitance of the transistor 170 at about 0.38 pF (and also less than the C_{gs} capacitance of the transistor 70 in FIG. 1). In that case, the C_{gs} capacitance of the transistor 171 contributes less capacitance to the filter unit 131 than the transistor 70 in FIG. 1 contributes to the filter unit 31. The C_{gs} of the each of the common drain transistors in the Darlington transistor pairs in the amplifier cells 121 and 122 also contribute less capacitance to the filter units 32 and 33, respectively.

With the use of the Darlington transistor pairs of the amplifier cells 120-122 in the distributed amplifier 100, the series capacitors (e.g., the series capacitor 80) relied upon in the distributed amplifier 10 shown in FIG. 1 can be omitted from the distributed amplifier 100 shown in FIG. 2. The use of the Darlington transistor pairs in the distributed amplifier 100 helps to achieve low NF and high linearity over a wide range of operating frequencies. The omission of the series capacitors used in the distributed amplifier 10 shown in FIG. 1 also saves space in integrated devices.

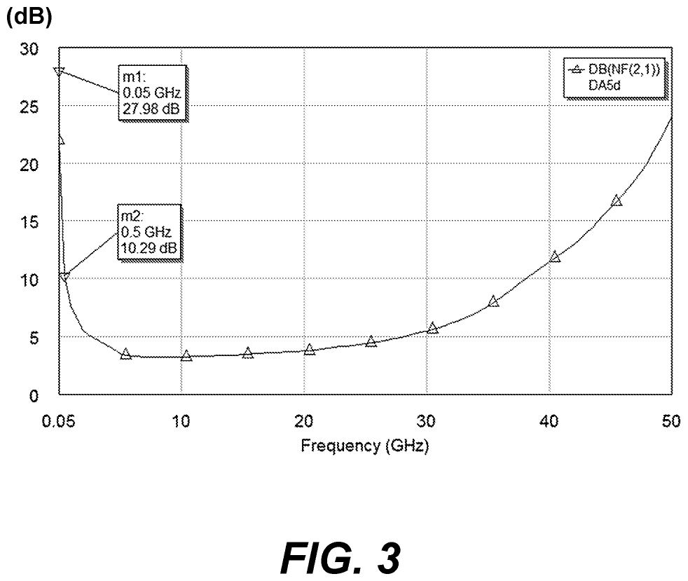

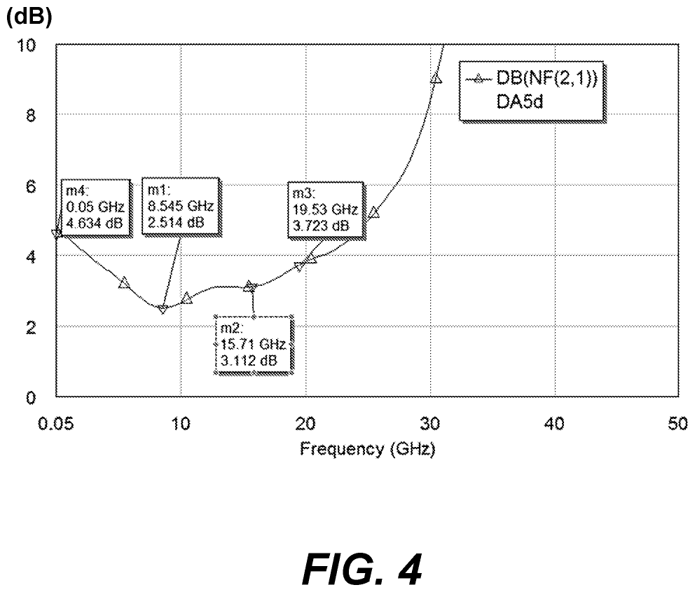

As a comparison of the operation of the distributed amplifiers 10 and 100, FIG. 3 illustrates the NF of the distributed amplifier 10 shown in FIG. 1, and FIG. 4 illustrates the NF of the distributed amplifier 100 shown in FIG. 2. At 50 MHz, the distributed amplifier 10 has 27 dB of NF as shown in FIG. 3. The distributed amplifier 100 has 4.6 dB of NF at 50 MHz as shown in FIG. 3. The lower NF value of 4.6 dB at 50 MHz for the distributed amplifier 100 is an improvement over the higher NF value of 27 dB at 50 MHz for the distributed amplifier 100. The distributed amplifier 100 demonstrates a lower NF value over a significant range of frequencies as compared to the distributed amplifier 10.

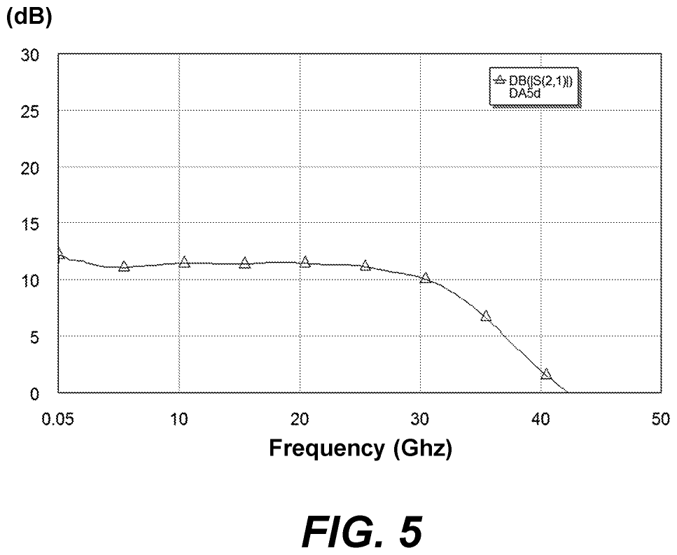

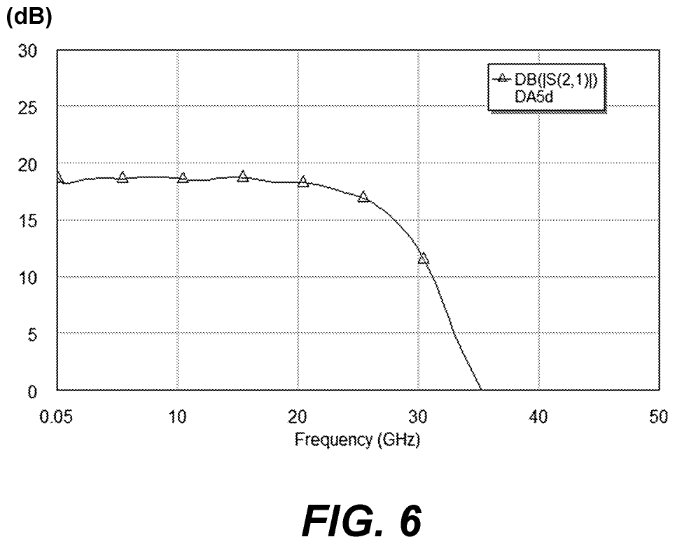

FIG. 5 illustrates the gain of the distributed amplifier 10 shown in FIG. 1, and FIG. 6 illustrates the gain of the distributed amplifier 100 shown in FIG. 2. As seen through a comparison of FIGS. 5 and 6, the distributed amplifier 100 has about 5-6 dB higher gain as compared to the distributed amplifier 10 over a significant frequency range. However, the distributed amplifier 10 has a wider overall bandwidth than the distributed amplifier 100 due to the lower equivalent C_{gs}.

The distributed amplifiers described herein, among others consistent with the concepts described herein, can be embodied in hardware or simulated as a number of circuit elements in software. Thus, a process for the evaluation of the distributed amplifier 10 shown in FIG. 1 can include simulating the circuit elements of the distributed amplifier 10 using one or more suitable TCAD simulation programs. Similarly, a process for the evaluation of the distributed amplifier 100 shown in FIG. 1 can include simulating the circuit elements of the distributed amplifier 100 using one or more suitable TCAD simulation programs.

If simulated in software, each circuit element can be embodied as a module or listing of code associated with certain parameters to simulate the element. The software to simulate the circuit elements can include program instructions embodied in the form of, for example, source code that includes human-readable statements written in a programming language or machine code that includes machine instructions recognizable by a suitable execution system, such as a processor in a computer system or other system. If embodied in hardware, each element can represent a circuit or a number of interconnected circuits.

One or more computing devices can execute the software to simulate the circuit elements that form the distributed amplifiers described herein, among others. The computing devices can include at least one processing circuit. Such a processing circuit can include, for example, one or more processors and one or more storage or memory devices coupled to a local interface. The local interface can include, for example, a data bus with an accompanying address/control bus or any other suitable bus structure.

The storage or memory devices can store data or components that are executable by the processors of the processing circuit. For example, data associated with one or more circuit elements of the distributed amplifiers can be stored in one or more storage devices and referenced for processing by one or more processors in the computing devices. Similarly, the software to simulate the circuit elements and/or other components can be stored in one or more storage devices and be executable by one or more processors in the computing devices.

Also, one or more or more of the components described herein that include software or program instructions can be embodied in any non-transitory computer-readable medium for use by or in connection with an instruction execution system such as, a processor in a computer system or other system. The computer-readable medium can contain, store, and/or maintain the software or program instructions for use by or in connection with the instruction execution system.

A computer-readable medium can include a physical media, such as, magnetic, optical, semiconductor, and/or other suitable media. Examples of a suitable computer-readable media include, but are not limited to, solid-state drives, magnetic drives, or flash memory. Further, any logic or component described herein can be implemented and structured in a variety of ways. For example, one or more components described can be implemented as modules or components of a single application. Further, one or more components described herein can be executed in one computing device or by using multiple computing devices.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A distributed amplifier device, comprising:
a plurality of distributed amplifier cells, respectively, comprising an input coupled to an input line and an output coupled to an output line;
a radio frequency input coupled to the input line; and
a radio frequency output coupled to the output line, wherein at least one of the plurality of distributed amplifier cells comprises a Darlington transistor pair.

2. The distributed amplifier device of claim 1, wherein the at least one of the plurality of distributed amplifier cells comprises a stacked cascode configuration of common gate transistors.

3. The distributed amplifier device of claim 1, wherein the Darlington transistor pair comprises a common drain transistor and a common source transistor, and a gate of the common source transistor is coupled to a source of the common drain transistor.

4. The distributed amplifier device of claim 3, wherein the common drain transistor comprises a gate width of a first size and the common source transistor comprises a gate width of a second size.

5. The distributed amplifier device of claim 4, wherein the gate width of the first size is smaller than the gate width of the second size.

6. The distributed amplifier device of claim 3, wherein the common drain transistor comprises a gate width of 50 μm and the common source transistor comprises a gate width of 120 μm.

7. The distributed amplifier device of claim 1, wherein the input line comprises a plurality of filter units in a constant-k filter transmission line input network.

8. The distributed amplifier device of claim 7, wherein a gate-source capacitance of at least one transistor in the Darlington transistor pair comprises a capacitance in a filter unit among the plurality of filter units.

9. The distributed amplifier device of claim 1, wherein:
the input line comprises a plurality of filter units in a transmission line input network;
the Darlington transistor pair comprises a common drain transistor and a common source transistor, and a gate of the common source transistor is coupled to a source of the common drain transistor;
the common drain transistor comprises a gate width of a smaller size to maintain a higher cut-off frequency for the distributed amplifier device; and
the common source transistor comprises a gate width of a larger size to increase a gain of the distributed amplifier device.

10. A distributed amplifier device, comprising:
a plurality of distributed amplifier cells, respectively, comprising an input coupled to an input line and an output coupled to an output line;
a radio frequency input coupled to the input line; and
a radio frequency output coupled to the output line, wherein:
at least one of the plurality of distributed amplifier cells comprises a Darlington transistor pair;
the Darlington transistor pair comprises a common drain transistor and a common source transistor; and
the common drain transistor comprises a gate width of a first size and the common source transistor comprises a gate width of a second size.

11. The distributed amplifier device of claim 10, wherein the at least one of the plurality of distributed amplifier cells comprises a stacked cascode configuration of common gate transistors.

12. The distributed amplifier device of claim 10, wherein the gate width of the first size is smaller than the gate width of the second size.

13. The distributed amplifier device of claim 10, wherein the common drain transistor comprises a gate width of 50 μm and the common source transistor comprises a gate width of 120 μm.

14. The distributed amplifier device of claim 10, wherein the input line comprises a plurality of filter units in a constant-k filter transmission line input network.

15. The distributed amplifier device of claim 14, wherein a gate-source capacitance of at least one transistor in the Darlington transistor pair comprises a capacitance in a filter unit among the plurality of filter units.

16. The distributed amplifier device of claim 10, wherein:
the input line comprises a plurality of filter units in a transmission line input network;
a gate of the common source transistor of the Darlington transistor pair is coupled to a source of the common drain transistor of the Darlington transistor pair;
the common drain transistor comprises a gate width of a smaller size to maintain a higher cut-off frequency for the distributed amplifier device; and
the common source transistor comprises a gate width of a larger size to increase a gain of the distributed amplifier device.

17. A distributed amplifier device, comprising:
at least one distributed amplifier cell in a distributed amplifier, the at least one distributed amplifier cell comprising an input, an output, and a Darlington transistor pair, wherein:
the Darlington transistor pair comprises a common drain transistor and a common source transistor; and
the common drain transistor comprises a gate width of a first size and the common source transistor comprises a gate width of a second size.

18. The distributed amplifier device of claim 17, wherein the gate width of the first size is smaller than the gate width of the second size.

19. The distributed amplifier device of claim 17, wherein the common drain transistor comprises a gate width of 50 μm and the common source transistor comprises a gate width of 120 μm.

20. The distributed amplifier device of claim 17, wherein:
a gate of the common source transistor of the Darlington transistor pair is coupled to a source of the common drain transistor of the Darlington transistor pair;
the common drain transistor comprises a gate width of a smaller size to maintain a higher cut-off frequency for the distributed amplifier device; and
the common source transistor comprises a gate width of a larger size to increase a gain of the distributed amplifier device.
